(19) United States
(12) Patent Application Publication
(10) Pub. No.: US 2014/0049292 A1
(43) Pub. Date: Feb. 20, 2014

(54) INTEGRATED CIRCUIT PACKAGE HAVING MEDIUM-INDEPENDENT SIGNALING INTERFACE COUPLED TO CONNECTOR ASSEMBLY

(71) Applicants: Petre Popescu, Ottawa (CA); Emerson S. Fang, Fremont, CA (US); Bruce A. Doyle, Longmont, CO (US); Alvin Leng Sun Loke, Fort Collins, CO (US); Shawn Searles, Austin, TX (US)

(72) Inventors: Petre Popescu, Ottawa (CA); Emerson S. Fang, Fremont, CA (US); Bruce A. Doyle, Longmont, CO (US); Alvin Leng Sun Loke, Fort Collins, CO (US); Shawn Searles, Austin, TX (US)

(73) Assignees: ATI TECHNOLOGIES ULC, Markham (CA); ADVANCED MICRO DEVICES, INC., Sunnyvale, CA (US)

(21) Appl. No.: 13/588,704

(22) Filed: Aug. 17, 2012

(51) Int. Cl. H01R 12/70; G02B 6/36; H03K 5/01

(52) U.S. Cl. 327/100; 439/55; 385/88

(57) ABSTRACT

An integrated circuit (IC) package includes electrical contacts disposed at a first surface of the IC package, an integrated circuit implementing an electrical signaling interface, and a connector assembly accessible at a second surface of the IC package. The connector assembly is to mechanically attach to another connector assembly and includes contact terminals electrically coupled to the electrical signaling interface. The connector assembly can be configured to provide friction coupling with the other connector assembly to permit the other connector assembly to be removably attached. A system includes the IC package and an external transceiver module having a connector assembly mechanically attached to the connector assembly of the IC package. The electrical signaling interface conducts signaling with the external transceiver module in accordance with one signal format and the external transceiver module conducts signaling over a transmission medium in accordance with another signal format.

### BACKGROUND

1. Field of the Disclosure

The present disclosure generally relates to signaling between integrated circuit packages.

2. Description of the Related Art

Electronic devices often implement multiple integrated circuit (IC) packages disposed at one or more printed circuit boards (PCB) or other inter-device substrates. In many conventional implementations, signaling between the IC packages is conducted via metal traces at one or more layers of the inter-device substrates. This approach has limited signal speeds due to noise introduced by the relatively long metal traces of the inter-device substrates, and is subject to excessive power consumption due to resistive and capacitive parasitics in the package-to-PCB signaling pathways. In an effort to address these issues, some electronic systems employ repeaters to improve end-to-end signal fidelity and thus permit greater signaling speeds. However, the use of repeaters often significantly increases power consumption and implementation costs. Other systems employ active optical cables to improve signal fidelity and speeds. In this approach, electrical/optical converter devices are implemented at the inter-device substrate to convert electrical signals to optical signals at the transmitting side and subsequently convert the optical signals back to electrical signals at the receiving side. However, this solution leads to considerable power consumption as the electrical signals must traverse between the IC packages and the active-optical cables via the inter-device substrates. Moreover, the use of external devices to repeat or translate inter-package signaling often inhibits refinement of the signaling interfaces of the IC packages as they either must remain backwards-compatible with legacy repeaters/active optical cables, or significant investment must be made to design and fabricate revised versions of the IC packages with new signaling interfaces that are compatible with new or revised signaling formats.

### BRIEF DESCRIPTION OF THE DRAWINGS

The present disclosure may be better understood, and its numerous features and advantages made apparent to those skilled in the art by referencing the accompanying drawings. The use of the same reference symbols in different drawings indicates similar or identical items.

FIG. 1 is a diagram illustrating a cross-section view of an electronic device having a pluggable cable removably attached to two integrated circuit (IC) packages in accordance with at least one embodiment of the present disclosure.

FIG. 2 is a diagram illustrating a cross-section view of an electronic device having a two IC packages in wireless communication via pluggable wireless transceiver modules in accordance with at least one embodiment of the present disclosure.

FIG. 3 is a diagram illustrating a perspective view of an IC package having a connector assembly to removably attach with a corresponding connector assembly of an external transceiver module in accordance with at least one embodiment of the present disclosure.

FIG. 4 is a diagram illustrating a cutaway view of the perspective view of the IC package of FIG. 3 in accordance with at least one embodiment of the present disclosure.

FIG. 5 is a diagram illustrating an example of a compatible connector assembly pair in accordance with at least one embodiment of the present disclosure.

FIG. 6 is a diagram illustrating another example of a compatible connector assembly pair in accordance with at least one embodiment of the present disclosure.

FIG. 7 is a diagram illustrating yet another example of a compatible connector assembly pair in accordance with at least one embodiment of the present disclosure.

FIG. 8 is a diagram illustrating a top-view perspective of an external transceiver module attached to an IC package in accordance with at least one embodiment of the present disclosure.

FIG. 9 is a diagram illustrating an example electrical/optical converter implementation of an external transceiver module in accordance with at least one embodiment of the present disclosure.

FIG. 10 is a diagram illustrating an example single-ended/differential signal converter implementation of an external transceiver module in accordance with at least one embodiment of the present disclosure.

FIG. 11 is a diagram illustrating an example wireless transceiver implementation of an external transceiver module in accordance with at least one embodiment of the present disclosure.

FIG. 12 is a flow diagram illustrating a method for designing and fabricating an integrated circuit (IC) package implementing a connector assembly and corresponding electrical signaling interface in accordance with at least one embodiment of the present disclosure.

### DETAILED DESCRIPTION

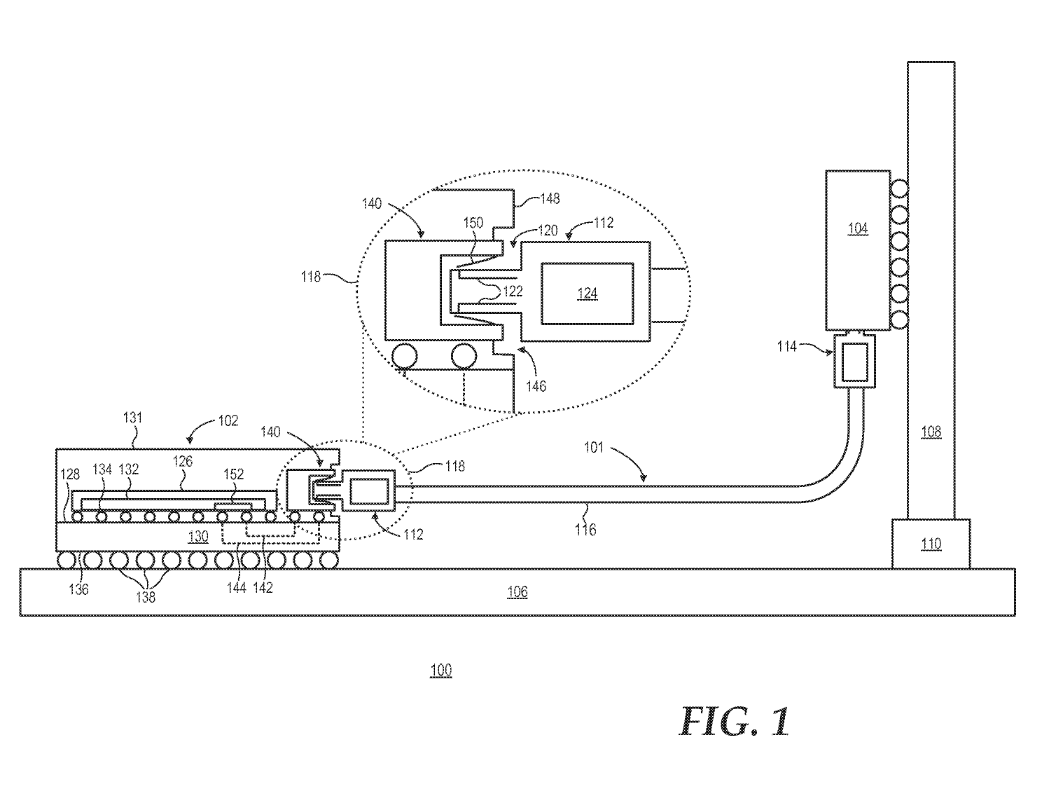

FIGS. 1-12 illustrate example techniques for conducting signaling for an integrated circuit (IC) package using an external transceiver module electrically and mechanically coupled to the IC package. In one embodiment, the IC package comprises an electronic signaling interface and a connector assembly coupled to the electronic signaling interface. The connector assembly is disposed at, or otherwise accessible at, a side surface or top surface of the IC package. The connector assembly of the IC package is configured to couple with a corresponding connector assembly of the external transceiver module so as to provide a mechanical attachment between the IC package and external transceiver module, as well as to provide an electrical signaling pathway between the electronic signaling interface of the IC package and transceiver circuitry of the external transceiver module. The transceiver circuitry of the external transceiver module receives signaling from the electronic signaling interface and converts the signaling to a signal format appropriate for the transmission medium of the external transceiver module. Likewise, the transceiver circuitry of the external transceiver module receives signaling from the transmission medium and converts the received signaling to an electronic signaling format suitable for the electronic signaling interface of the IC package. By implementing a connector assembly at a side surface or top surface of the IC package, the IC package can conduct signaling with other devices without requiring a conductive pathway through the package substrate of the IC package and into the printed circuit board (PCB) or other inter-device substrate, thus reducing the package-to-PCB pin count necessary to support the signaling of the IC package, as well as the number of metal layers needed in the PCB, while also avoiding the power consumed by the resistive and capacitive parasitics present in the IC package-to-PCB signal pathway.

In one embodiment, the connector assembly of the IC package and the corresponding connector assembly of the external transceiver module are configured to provide a “press fit” relationship whereby the connector assemblies form a friction coupling that helps maintain the connector assemblies in position under expected operational conditions. This press fit relation thereby allows the external transceiver module to be removably attachable to the IC package, and thus permits swapping between different external transceiver modules so as to communicate over different transmission mediums. A retention element, such as a pin, clamp, or lever, also may be used to maintain the mechanical attachment between connector assemblies. In one embodiment, the external transceiver module is implemented as one head end of a cable, whereby the transmission medium of the cable can comprise wire conductors or optical waveguides. The other head end of the cable can comprise another external transceiver module that attaches to another IC package, or a conventional cable end to attach to, for example, an active optical cable package or other IC transceiver package. In another embodiment, the transmission medium comprises a wireless medium, such as a radio frequency (RF) or infrared (IR) medium, and thus the external transceiver module can comprise a wireless transceiver module that converts outgoing electrical signaling from the IC package to RF or IR signals, and converts incoming RF or IR signals to electrical signaling for processing by the IC package.

In one embodiment, the electrical signaling interface implemented at the IC package comprises a broadly-compatible electrical signaling interface that is not specific to the transmission medium between the IC packages (and hence referred to herein as “medium independent”). Thus, the external transceiver module is responsible for converting between medium-independent signaling format provided to/from the electrical signaling interface and the medium-dependent signaling format used to communicate signaling over the transmission medium. For example, if the transmission medium comprises wire pairs intended for differential signaling, rather than implement a differential signaling transceiver as the electrical signaling interface of the IC package, the electrical signaling interface instead may implement a single-ended transceiver and the external transceiver module would thus implement circuitry for converting the single-ended format of the signaling from the electrical signaling interface to a differential format appropriate for transmission over the wire pair of the transmission medium. Likewise, the external transceiver module would implement circuitry for converting signaling received from the wire pairs from a differential format to a single-ended format for reception and processing by the IC package. As another example, the signaling format conversion provided by the external transceiver module can include conversion from an electrical signaling format to an optical signaling format and vice versa, conversion from an electrical signaling format to an RF signaling format and vice versa, conversion from an electrical signaling format to an IR signaling format and vice versa, and the like.

By implementing a medium-independent signaling interface at the IC package and implementing a medium-dependent signaling interface at the external transceiver module, the same IC package design can be implemented in any of a variety of signaling environments by selecting a particular external transceiver module suited for the desired transmission medium. To illustrate, the same IC package can be used in both a device that calls for optical signaling between components and a device that calls for wireless signaling between components by selecting and attaching an external transceiver module implementing electrical/optical conversion in the first instance and by selecting and attaching an external transceiver module implementing electrical/wireless conversion in the second instance. Moreover, because the IC package can implement a relatively simple and widely adopted single-ended signaling interface, the IC package can be compatible with new system architectures having signal formats that change and evolve by implementing different or revised external transceiver modules, and thus making it unnecessary to redesign the IC package to accommodate new signal formats.

For ease of illustration, the example embodiments of the present disclosure are described in the context of a full-duplex link (that is, separate transmit and receive paths) inter-package transmission medium. However, the techniques described herein may be implemented in half-duplex (that is, a shared transmit/receive path) or unidirectional (that is, one-way) inter-package communications without departing from the scope of the present disclosure. Accordingly, unless otherwise noted, reference to “transceiver” can include reference to a transmitter, a receiver, or a combination of a transmitter and a receiver. Moreover, these example embodiments are described in a context whereby the bi-directional inter-package transmission medium comprises one upstream channel and one downstream channel. However, these techniques are not limited to this example implementation, but instead may include multiple upstream channels and multiple downstream channels. Moreover, some applications may implement multiple links that can be included in one transceiver, or use separate transceivers for each link. Additionally, one or more upstream channels and one or more downstream channels may share the same physical transmission medium using any of a variety of duplexing techniques, such as time division multiplexing, frequency division multiplexing, and the like.

FIG. 1 illustrates a cross-section view of an electronic device 100 implementing an inter-package cable 101 to conduct signaling between IC packages 102 and 104 in accordance with at least one embodiment of the present disclosure. The electronic device 100 may comprise, for example, a desktop computer, a notebook or tablet computer, a server, a network router, a computing-enabled cellular phone, a television or other display, a set-top box, a video game console, and the like. The electronic device 100 includes the inter-package cable 101, the IC packages 102 and 104 and printed circuit boards (PCBs) 106 and 108. In the depicted example, the PCB 106 comprises a motherboard and the PCB 108 comprises a daughterboard connected to the motherboard via a slot 110, and whereby the IC package 102 is disposed at the PCB 106 and the IC package 104 is disposed at the PCB 108. The IC packages 102 and 104 can comprise any of a variety of devices, such as an application specific integrated circuit (ASIC), a programmable device, such as a field programmable gate array (FPGA), and the like. Examples of such devices include, but are not limited to, processor devices (e.g., a central processing unit (CPU), a graphics processing unit (GPU), an accelerated processing unit (APU), or digital signal processor (DSP)), microcontrollers, multimedia encoders/decoders/transcoders, and the like. The IC package 102 and the IC package 104 may comprise the same type of device or different device types. For example, the IC package 102 can comprise a processor device and the IC package 104 can comprise another processor device, a display controller, a disc drive controller, a peripheral component controller, and the like.

The inter-device cable 101 includes two transceiver modules 112 and 114 (as cable heads) coupled via a cable body 116. As illustrated by expanded view 118, each of the transceiver modules 112, 114 includes a connector assembly 120 having contact terminals 122 electrically coupled to transceiver circuitry 124. The transceiver circuitry 124, in turn, is coupled to a transmission medium of the cable body 116. The transmission medium, in one embodiment, includes an electrically conductive medium (e.g., metal wires). In another embodiment, the transmission medium includes an optical transmission medium (e.g., optical waveguides). The inter-device cable 101 conducts signaling between the IC package 102 and 104 via the transmission medium of the cable body 116. In one embodiment, the transceiver module proximate to the transmitting IC package receives electrical signaling from the transmitting IC package, uses the transceiver circuitry 124 to convert the received electrical signaling from a medium-independent signaling format to a medium-dependent signaling format appropriate for transmission over the transmission medium of the cable 101, and transmits the converted signaling to the other transceiver module via the transmission medium. At the receiving end, the transceiver module proximate to the receiving IC package converts the converted signaling back to the original signaling format (or other signaling format appropriate for the receiving IC package) and provides the reconverted signaling to the receiving IC package. This process is described in greater detail below.

The IC package 102 includes one or more dies 126 (also referred to as “chips”) disposed at a top surface 128 of a package substrate 130, whereby the one or more dies and at least the top surface 128 of the package substrate 130 are encapsulated or otherwise enclosed by an encapsulating structure 131 (which may include a package lid) to form the IC package 102. Bond pads of integrated circuitry formed at an active surface 132 of the die 126 are coupled to corresponding bond pads at the top surface 128 of the package substrate 130 via intra-device contacts 134 (e.g., C4 bumps, microbumps, solder balls or other solder joints, pins, and the like). In turn, bond pads at the bottom surface 136 of the package substrate 130 are connected to corresponding bond pads of the PCB 106 via inter-device contacts 138. The package substrate 130 further includes metal interconnect structures (metal traces and inter-layer vias) to provide various electrical connections between bond pads of the package substrate 130.

The example depicted in FIG. 1 comprises a controlled collapse chip connection (C4) arrangement (also frequently referred to as a “flip chip”) whereby the active surface 132 of the die 126 faces the top surface 128 of the package substrate 130 and the intra-device contacts 134 comprise solder bumps formed from reflowed solder balls (also commonly referred to as C4 bumps). Further, in the depicted example, the IC package 102 implements a land grid array (LGA) pin arrangement whereby the inter-device contacts 138 comprise solder joints formed from reflowed solder balls or pins of an IC socket (not shown) of the PCB 106. However, the present disclosure is not limited to these embodiments, and instead comprises any of a variety of IC packaging arrangements. To illustrate, the die 126 may be coupled to the package substrate 130 via wirebonding, and the IC package 102 may implement any of a variety of through-hole packaging arrangements, such as dual-inline package (DIP) arrangement, any of a variety of surface mount packaging arrangements, such as the aforementioned LGA arrangement or a column grid array (CGA) arrangement, any of a variety of chip carrier arrangements, such as a leaded chip carrier (LCC) arrangement, any of a variety of flat package arrangements, such as a quad flat package (QFP) arrangement, and the like. Although FIG. 1 illustrates an example implementation of the IC package as a system on a chip (SOC) whereby the die 126 comprises a substrate separate from the package substrate 130, in other embodiments the die 126 may comprise the package substrate 130 as well.

The IC package 102 further comprises a connector assembly 140 disposed at the top surface 128 of the package substrate 130 and electrically connected to the integrated circuitry of the die 126 via one or more intra-device contacts 134 and one or more metal structures (e.g., metal structures 142 and 144) of the package substrate 130. As illustrated by enlarged view 118, the connector assembly 140 is positioned at, or otherwise accessible via, an aperture 146 at a surface 148 of the IC package 102 and includes contact terminals 150 electrically coupled to an electrical signaling interface 152 of the integrated circuitry of the die 126. In the depicted example, the aperture 146 is disposed at a side surface of the IC package 102 (that is, a surface substantially perpendicular with the surface of the IC package 102 facing the package substrate 130) and aligned with a socket opening or terminal plug of the connector assembly 140. In other embodiments, the connector assembly 140 and the aperture 146 may be disposed at a top surface of the IC package (that is, the surface opposite the surface of the IC package 102 facing the package substrate 130). The connector assembly 140 further includes a housing to mechanically attach the connector assembly 140 to a corresponding housing of the connector assembly 120 such that the contact terminals 150 of the connector assembly 140 are brought into physical and electrical contact with the corresponding contact terminals 122 of the connector assembly 120, thereby electrically coupling the integrated circuitry of the die 126 with the transceiver circuitry 124 of the transceiver module 112.

In at least one embodiment, the connector assemblies 120 and 140 are removably attachable (i.e., “pluggable”) with respect to each other. To this end, the connector assemblies 120 and 140 can be compatibly configured so as to provide a press-fit relationship between the connector assembly 120 and the connector assembly 140. That is, the physical shape and dimensions of the connector assembly 120 and the physical shape and dimensions of the connector assembly 140 are such that the connector assemblies 120 and 140 may be maintained in mechanical and electrical contact through a friction coupling. To illustrate, in the depicted example of FIG. 1, the connector assembly 150 comprises a socket assembly (“a female connector”) having a socket opening with spring terminals (one embodiment of the contact terminals 150) and the connector assembly 120 comprises a terminal plug-type assembly (“a male connector”) having flat terminals (one embodiment of the contact terminals 122) disposed at opposite sides of the terminal plug. In this example, the friction coupling generated by the spring terminals pressing on the flat terminals provides a friction coupling sufficient to maintain mechanical attachment between the connector assemblies 120 and 140 under expected loading, while also enabling the connector assembly 120 to be repeatedly inserted into, and removed from, the connector assembly 140 as necessary. Other retention elements, such as levers, clamps, screws, and the like, may be used in addition to, or instead of, a press-fit arrangement in order to provide a secure mechanical attachment between the connector assemblies 120 and 140. Additional examples of the connector assemblies 120 and 140 are described in greater detail below.

In one embodiment, the external transceiver module 114 and the IC package 104 may be configured in a similar manner, such that the transceiver module 114 “plugs into” the IC package 104 via an aperture in the side or top of the IC package 104. In another embodiment, the IC device 104 comprises a conventional IC package and thus the transceiver module 114 communicates signaling between the cable 101 and the IC package 104 via metal traces of the PCB 108 and the inter-device contacts 138 of the IC package 104.

In conventional implementations, the IC packages 102 and 104 would be either electrically coupled via metal trace paths formed through metal traces in the PCB 106, the PCB 108 and the socket 110, or coupled via an active optical cable having one end disposed at the PCB 106 proximate to the IC package 102 and the other end disposed at the PCB 108 proximate to the IC package 104. Either approach would require electrical signaling to traverse a metal trace of one of the PCBs and traverse an inter-device contact 138 of the corresponding IC package. As such, the PCB may require additional metal layers and the IC packages would require additional inter-device contacts 124 to conduct this signaling, and unnecessary power would be consumed through resistive and capacitive parasitic present in the signal pathways formed by the inter-device contacts 138 and metal traces of the PCBs. However, by providing a connector assembly at a side or top surface of the IC packages 102 and 104, the IC packages 102 and 104 may be coupled to an inter-package transmission medium in a manner that avoids the package substrate-PCB interface, and thus requires fewer package pins and less energy expended per bit transmitted. Moreover, as the cable 101 can implement transceiver circuitry 124 suitable for the transmission medium of the cable body 116, the electrical signal interface 152 can implement a driver/receiver design that is independent of the particular transmission medium. In this way, it may not be necessary to modify the design of the IC packages 102 and 104 to take advantage of a variety of transmission mediums or in response to development of new signal transmission formats or protocols. Rather, under this approach, it is the design of the cable 101 that is adapted or revised in view of advancements in signaling formats or protocols, or it is a particular type of cable selected for use as the cable 101 in view of a particular signaling requirement.

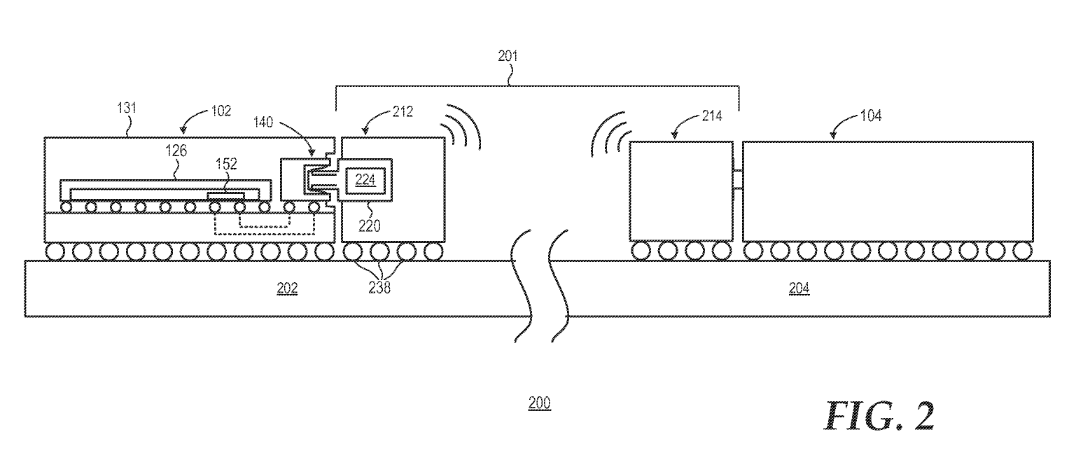

FIG. 2 illustrates a cross-section view of an electronic device 200 implementing a wireless transmission medium 201 to conduct signaling between the IC packages 102 and 104 in accordance with at least one embodiment of the present disclosure. As with the electronic device of FIG. 1, the electronic device 200 of FIG. 2 can comprise any of a variety of electronic devices. In the depicted example, the IC package 102 is disposed at a substrate portion 202 and the IC package 104 is disposed at a substrate portion 204, whereby the substrate portions 202 and 204 may be portions of the same inter-device substrate or different inter-device substrates. The wireless transmission medium 201 includes wireless transceiver modules 212 and 214 in wireless communication, whereby the wireless transceiver module 212 is disposed proximate to the IC package 102 at the substrate portion 202 and the wireless transceiver module 214 is disposed proximate to the IC package 104 at the substrate portion 204. Note that while FIG. 2 illustrates an example whereby the IC packages 102 and 104 are in the same device, in other embodiments the IC packages 102 and 104 may be in separate devices, such as one IC package in a computing device and the other IC package in a wireless display device.

The wireless transceiver module 212 includes one or more antennas (not shown), wireless transceiver circuitry 224, and a connector assembly 220 mechanically and electrically attached to the connector assembly 140 of the IC package 102 so as to electrically connect the electrical signaling interface 152 of the die 126 with the wireless transceiver circuitry 224 of the wireless transceiver module 214. In the depicted example, the wireless transceiver module 212 includes an IC package having inter-device contacts 238 coupled to bond pads of the substrate portion 202, whereby the inter-device contacts 238 can be used to provide supply voltages to the wireless transceiver module 212, conduct signaling between the wireless transceiver module 212 and other components of the electronic device 200, as well as to provide a mechanism for mechanically securing the wireless transceiver module 212. Although FIG. 2 illustrates the wireless transceiver module 212 coupled to the substrate portion 202 via solder balls (one embodiment of the inter-device contacts 238), other inter-device contacts may be implemented, such as C4 bumps, pins, etc. Moreover, the wireless transceiver module 212 may be coupled to the substrate portion 202 via another connector. In one embodiment, the wireless transceiver module 214 is similarly configured with respect to the IC package 104.

In operation, electrical signaling generated by the electrical signaling interface 152 of the die 126 is provided to the wireless transceiver circuitry 224 of the wireless transceiver 212 via the connector assemblies 140 and 220. The wireless transceiver circuitry 224 converts the electrical signaling to wireless signaling for transmission to the wireless transceiver module 214. Similarly, the wireless transceiver circuitry 224 receives wireless signaling from the wireless transceiver module 214, converts the wireless signaling to electrical signaling, and transmits the resulting electrical signaling to the electrical signaling interface 152 of the die 126 via the connector assemblies 140 and 220. The wireless transceiver circuitry of the wireless transceiver module 214 can be configured to operate in the same manner with respect to the IC package 104 or to operates as a standalone transceiver (e.g., as a wireless display device). The wireless signaling can include radio frequency (RF) signaling, and the wireless transceiver circuitry 224 thus can include, for example, a Bluetooth-compliant transceiver, a ZigBee RF4CE-compliant transceiver, IEEE 802.11-compliant transceiver (e.g., a WiGig 60 Gigaherz transceiver), or an RF transceiver implementing a proprietary RF signal format. Alternatively, the wireless signaling can include infrared (IR) signaling, and the wireless transceiver circuitry 224 thus can include an IR transceiver compatible with an industry-standard or proprietary IR signaling format. An example implementation of the wireless transceiver circuitry 224 is described below with reference to FIG. 11.

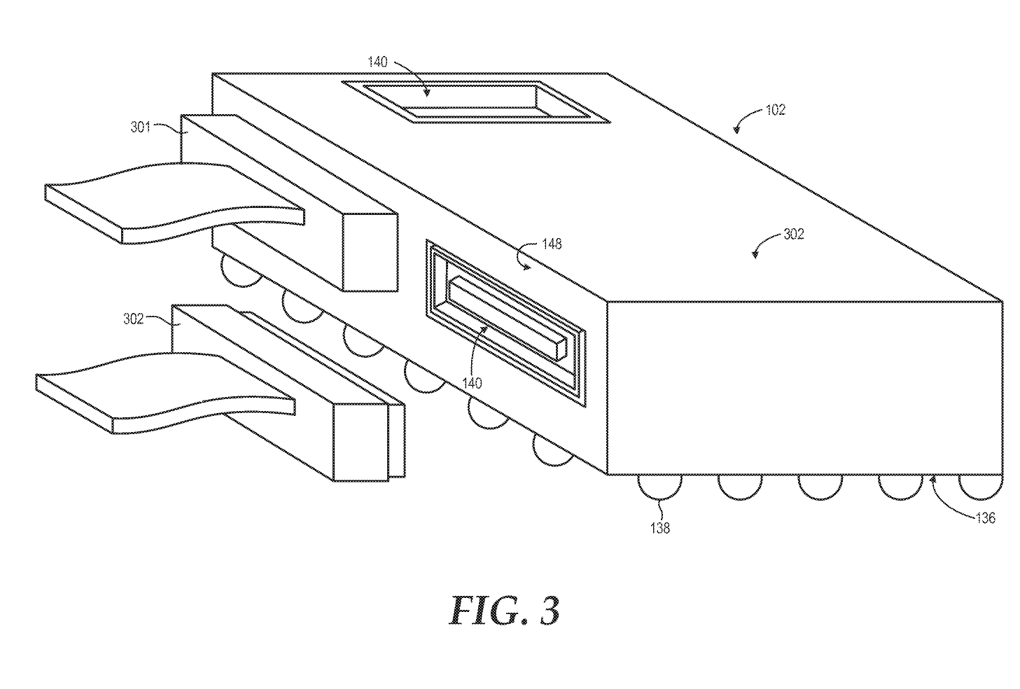

FIG. 3 illustrates a perspective view of the IC package 102 implementing one or more connector assemblies for coupling to an inter-package transmission medium in accordance with at least one embodiment of the present disclosure. As described above, the IC package 102 includes a plurality of inter-device contacts 138 disposed at the bottom surface 136 and one or more connector assemblies 140 disposed at one or more surfaces of the IC package 102 other than the bottom surface 336. For example, the IC package 102 can include one or more connector assemblies 140 disposed at a side surface 148. As another example, the IC package 102 can include one or more connector assemblies 140 at a top surface 302 (e.g., at a package lid of the IC package). In some implementations, a heat sink may be disposed at the package lid of the IC package 102, and in such instances either the heat sink will need to have an aperture aligned with the aperture in the package lid that provides access to a top-positioned connector assembly 140, or a side-positioned connector assembly 140 is to be used. As described above, the connector assemblies of the IC package 102 are configured to mechanically and electrically couple with corresponding connector assemblies of inter-package transmission mediums so as to provide electrical signaling paths between the inter-package transmission mediums and electrical signaling interfaces of one or more die of the IC package 102. In the depiction of FIG. 3, one connector assembly (not shown) at the side surface 148 is mechanically and electrically attached to an inter-package cable 301 (corresponding to the inter-package cable 101 of FIG. 1) and an inter-package cable 302 is in the process of being plugged into another connector assembly 140 at the side surface 148. Alternatively, other transmission modules, such as the wireless transmission modules 212 and 214 described above, may be attached to one or both of the connector assemblies at the side surface 148.

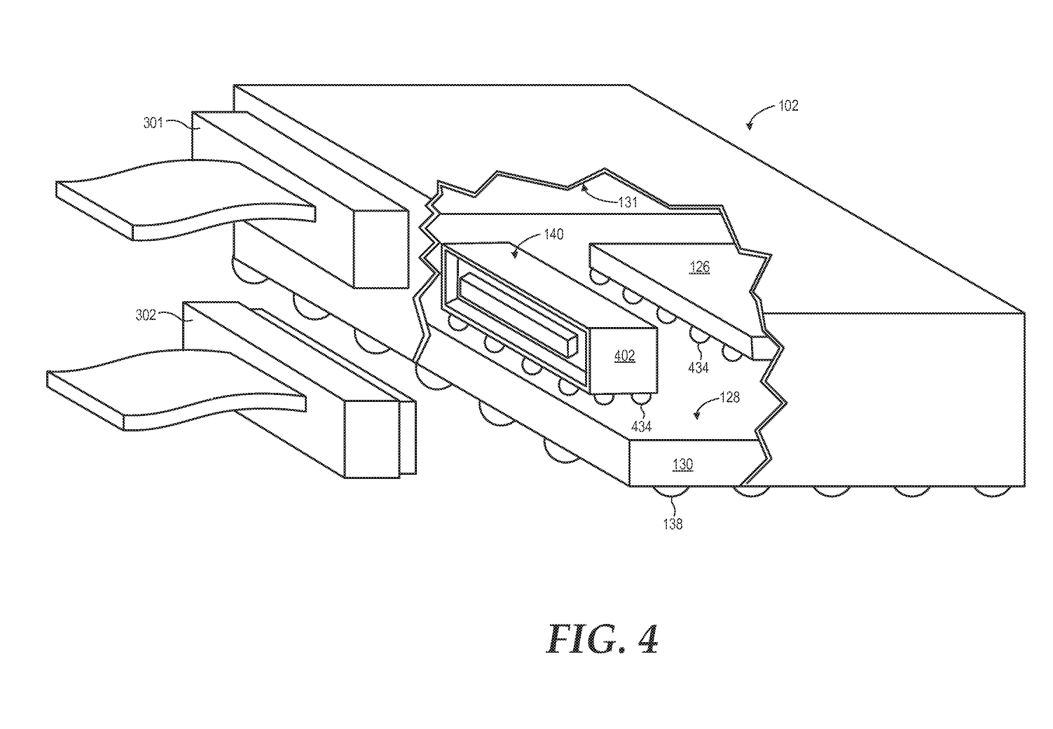

FIG. 4 illustrates a cut-away view of the IC package 102 of FIG. 3 in accordance with at least one embodiment of the present disclosure. As illustrated by the cut-away view, the connector assembly 140 includes a connector housing 402 disposed at the top surface 128 of the package substrate 130, whereby the connector assembly 140 may be mechanically and electrically coupled to the package substrate 130 via solder joints 434 (one embodiment of the intra-device contacts 134). Also disposed at the package substrate 130 is the die 126 implementing the electrical signaling interface 152 (FIG. 1) and coupled to the package substrate 130 via solder joints 434. The connector housing 402 of the connector assembly 140 and the die 126 are encapsulated in an encapsulant, thereby forming encapsulating structure 131 of the IC package 102. The encapsulating structure 131 includes the aperture 146 (FIG. 1) to permit external access to a socket opening or terminal plug of the connector housing 402 of the connector assembly 140.

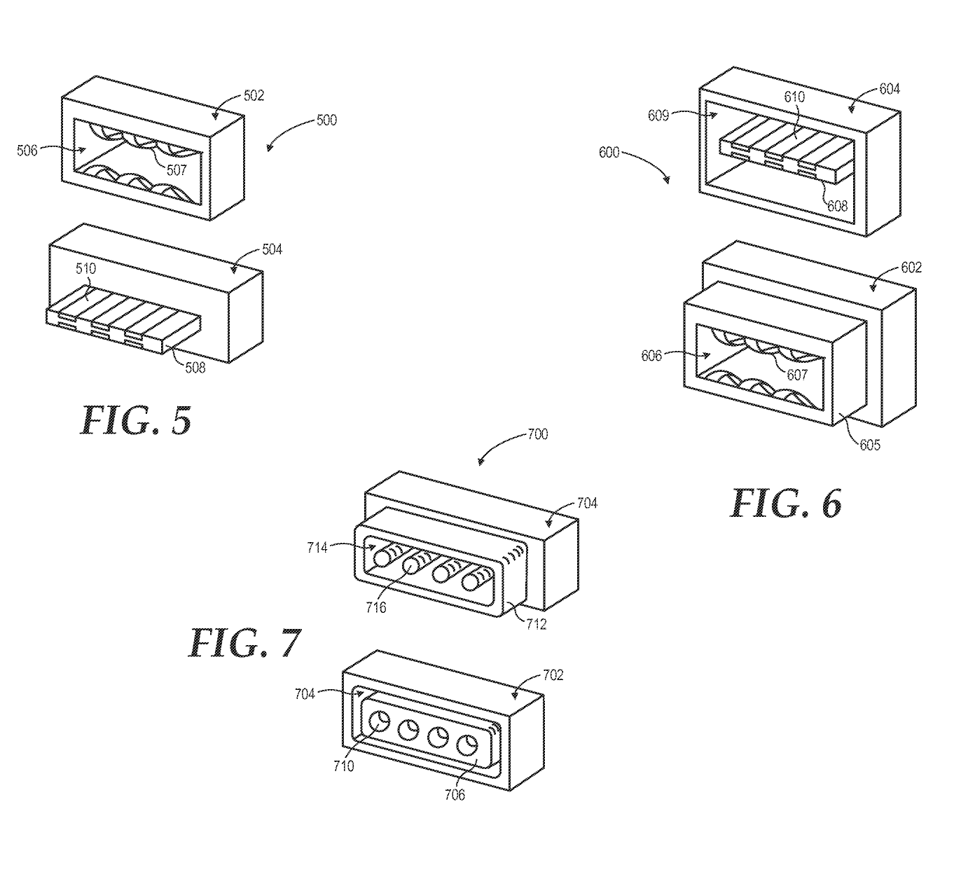

FIGS. 5-7 illustrate various example types of compatible connector assembly pairs that may be implemented as the connector assembly 140 (IC package)/connector assembly 120 (external transceiver module) pair in accordance with at least one embodiment of the present disclosure. Although various example implementations are disclosed, the present disclosure is not limited to these examples. Rather, the connector assemblies 120 and 140 may be implemented using any of a variety of suitable connector assemblies, either those commercially available or those developed through proprietary design.

FIG. 5 depicts an example of a compatible connector assembly pair 500 comprising a socket assembly 502 (“female terminal”) compatible with a terminal plug assembly 504 (“male terminal”). The connector assembly 140 of the IC package 102 may implement the socket assembly 502 and the connector assembly 120 of the external transceiver module 112/212 may implement the terminal plug assembly 504, or vice versa. The socket assembly 502 comprises a socket opening 506, in which a plurality of spring-type contact terminals 507 are disposed at a top and bottom side of the socket opening 506. The terminal plug assembly 504 includes a terminal plug 508 having a plurality of flat contact terminals 510 disposed on top and bottom surfaces of the terminal plug 508. The terminal plug 508 and the flat contact terminals 510 are dimensioned and positioned so that when the socket assembly 502 and the terminal plug assembly 504 are brought together, each spring-type contact terminal 507 comes into physical and electrical contact with a corresponding flat contact terminal 510 and introduces a correspond frictional force, the sum of which maintains the socket assembly 502 and terminal plug assembly 504 in mechanical and electrical contact under anticipated operational conditions, while also permitting the socket assembly 502 and terminal plug assembly 504 to be repeatedly separated and reattached.

FIG. 6 depicts an example of a compatible connector assembly pair 600 comprising a socket assembly 602 compatible with a terminal plug assembly 604. The connector assembly 140 of the IC package 102 may implement the socket assembly 602 and the connector assembly 120 of the external transceiver module 112/212 may implement the terminal plug assembly 604, or vice versa. The socket assembly 602 comprises a housing forming a plug 605, which in turn forms a socket opening 606, in which a plurality of spring-type contact terminals 607 are disposed at a top and bottom side of the socket opening 606. The terminal plug assembly 604 includes a housing forming a socket opening 609, in which a plug 608 is positioned. The plug 608 has a plurality of flat contact terminals 610 disposed on top and bottom surfaces of the plug 608. The plug 608 and the flat contacts 610 are dimensioned and positioned so that when the socket assembly 602 and the terminal plug assembly 604 are brought together, each spring-type contact terminal 607 comes into physical and electrical contact with a corresponding flat contact terminal 610 and introduces a correspond frictional force that helps maintain the socket assembly 602 and terminal plug assembly 604 in mechanical and electrical contact under expected operational conditions. Moreover, the outer surfaces of the plug 605 and the inner surfaces of the socket opening 609 are compatibly dimensioned so as to provide a friction coupling between the plug 605 and the socket opening 609, thereby facilitating a “press-fit” relationship that maintains the socket assembly 602 and terminal plug assembly 604 in mechanical contact under expected operational conditions, while also permitting the socket assembly 602 and terminal plug assembly 604 to be repeatedly separated and reattached.

FIG. 7 depicts an example of a compatible connector assembly pair 700 comprising a socket assembly 702 compatible with a terminal plug assembly 704. The connector assembly 140 of the IC package 102 may implement the socket assembly 702 and the connector assembly 120 of the external transceiver module 112/212 may implement the terminal plug assembly 704, or vice versa. The socket assembly 702 comprises a housing forming a socket opening 704, in which a plug 706 is disposed. The plug 706 comprises a plurality of pin holes 710. The pin holes 710 each includes a corresponding electrical contact in the form of, for example, a conductive hole wall or a recessed metal spring or spring-mounted recessed pin. The terminal plug assembly 704 includes a housing that forms a plug 712, which in turn forms a socket opening 714. A plurality of contact pin terminals 716 is disposed in the socket opening 714. The contact pin terminals 716 and the pin holes 710 are dimensioned and positioned so that when the socket assembly 702 and the terminal plug assembly 704 are brought together, each contact pin terminal 716 comes into electrical and physical contact with a corresponding pin hole 710. Moreover, the outer surfaces of the plugs 706 and 712 and the inner surfaces of the socket openings 704 and 714 are compatibly dimensioned so as to provide a friction coupling between the plug 706 and the socket opening 714 and a friction coupling between the plug 712 and the socket opening 704, thereby facilitating a “press-fit” relationship that maintains the socket assembly 702 and terminal plug assembly 704 in mechanical contact under expected operational conditions, while also permitting the socket assembly 702 and terminal plug assembly 704 to be repeatedly separated and reattached.

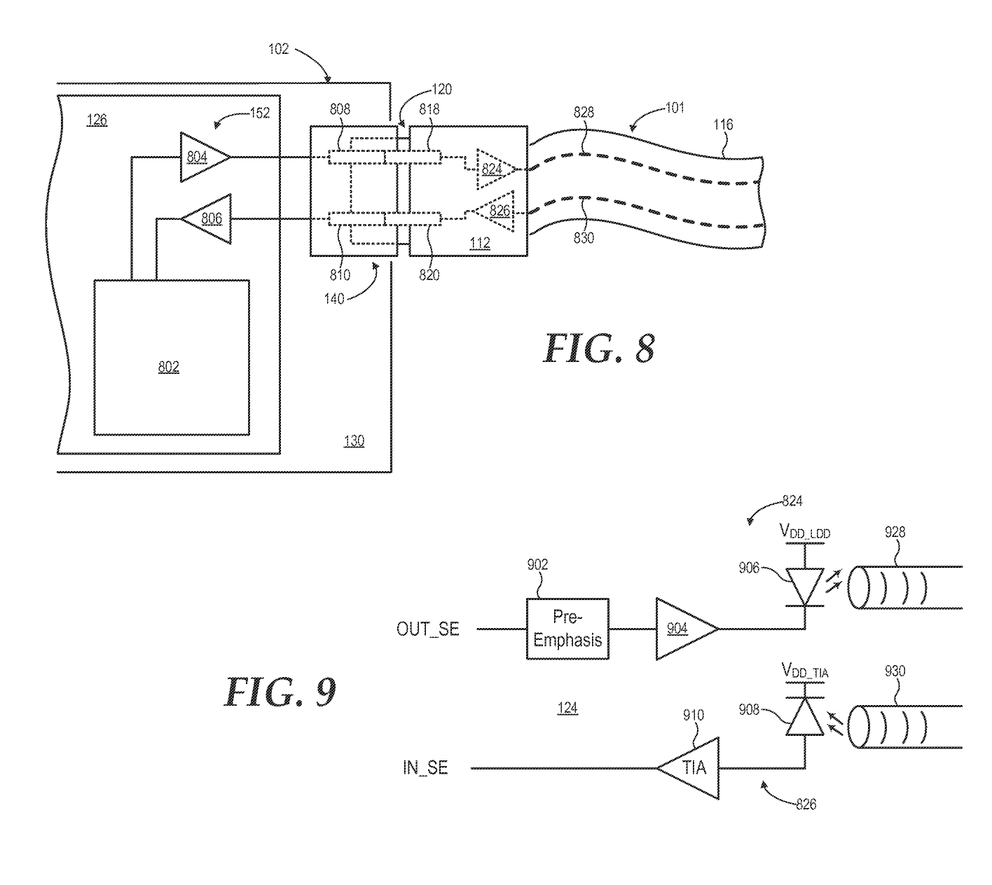

FIG. 8 illustrates a diagrammatic top-view of the IC package 102 in mechanical attachment with the external transceiver module 112 in accordance with at least one embodiment of the present disclosure. For purposes of illustration, FIG. 8 is described in the context of the inter-package cable 101 of FIG. 1, but the same principles described below apply to the context of the wireless medium 201 of FIG. 2 or another transmission medium. As described above, the IC package includes the die 126 and connector assembly 140 disposed at the package substrate 130. The connector assembly 140 is attached to the connector assembly 120 of the external transceiver module 112 of the inter-package cable 101. The external transceiver module 112 forms a cable head of the cable 101 and is fixedly attached to the cable body 116.

The die 126 includes integrated circuitry including the electrical signaling interface 152 coupled to signal processing circuitry 804, which generates signals to be transmitted by the electrical signaling interface 152 and which processes signals received from the electrical signaling interface 152. In the depicted example, the electrical signal interface 152 comprises a serial interface comprising a line driver 804 and line receiver 806. The line driver 804 comprises an input coupled to an output of the signal processing circuitry 802 and comprises an output coupled to contact terminal 808 of the connector assembly 140. The line receiver 806 comprises an input coupled to a contact terminal 810 of the connector assembly 140 and an output coupled to an input of the signal processing circuitry 802.

The external transceiver module 112 includes the transceiver circuitry 124 and the connector assembly 120. The connector assembly 120 includes contact terminals 818 and 820, which correspond to contact terminals 808 and 810, respectively, of the connector assembly 140. The transceiver circuitry 124 includes a driver 824 and a receiver 826. The driver 824 includes an input coupled to the contact terminal 818 and an output coupled to a transmission line 828 of the cable body 116. The receiver 826 includes an input coupled to a transmission line 830 of the cable body 116 and an output coupled to the contact terminal 820. In one embodiment, the transmission lines 828 and 830 comprise optical waveguides and thus the driver 824 comprises an electrical-to-optical converter and the receiver 826 comprises an optical-to-electrical converter. In another embodiment, the transmission lines 828 and 830 each comprise a differential wire pair (such as a twisted pair) and thus the driver 824 comprises a differential signal driver and the receiver 826 comprises a differential signal receiver.

The connector assemblies 120 and 140 and the contact terminals 808, 810, 818, and 820 are dimensioned and positioned such that when the connector assemblies 120 and 140 are brought together (that is, the cable 101 is plugged into the IC package 102), the connector assemblies 120 and 140 are mechanically attached through a friction coupling, the contact terminal 808 is brought into physical and electrical contact with the contact terminal 818, and the contact terminal 810 is brought into physical and electrical contact with the contact terminal 820. In this manner, a conductive path is formed between the output of the line driver 804 and the input of the driver 824 and a conductive path is formed between the output of the receiver 826 and the input of the receiver 806. Accordingly, an output signal provided by the signal processing circuitry 802 is driven by the line driver 804 to the driver 824, which converts the output signal into a signal format suitable for the transmission line 828 and drives the converted output signal onto the transmission line 828. Conversely, a signal received over the transmission line 830 is converted by the receiver 826 to a signal format suitable for the line receiver 806, which in turn drives the converted received signal to the signal processing circuitry 802. The transmission lines 828 and 830 may be implemented using commercially available or proprietary electrical cables or optical waveguides.

In one embodiment, the line transmitter 804 and the line receiver 806 of the IC package 102 are medium-independent and the transmitter 824 and the receiver 826 of the external transceiver module 112 are medium-dependent in that the line transmitter 804 transmits signaling and the line receiver 806 receives signaling in a signal format that is independent of the signaling format used for the inter-package transmission medium (e.g., the transmission lines 828 and 830), whereas the transmitter 824 is responsible for converting the signaling to a signal format appropriate for the inter-package transmission medium and the receiver is responsible for converting the signaling from the signal format of the inter-package transmission medium. Thus, to facilitate interoperability with a variety of external transceiver modules and a variety of transmission mediums, in one embodiment the line driver 804 and line receiver 806 implement a relatively simple and relatively easily convertible signaling format, such as a single-ended serial electrical signal format. Thus, the line transmitter 804 can include a single-ended line driver and the line receiver comprises a single-ended line receiver 806. Under this approach, the same IC package can be with various transmission mediums by selecting the appropriate external transceiver module for the transmission medium. Further, in the event that a new or revised signaling format is developed, rather than revising the design of the IC package (which often is an expensive and time-consuming task), the design of the external transceiver module instead may be revised (which often is a less expensive and less-time consuming task).

FIGS. 9-11 illustrate various example implementations of the transceiver circuitry 124 of the external transceiver module 112 of FIG. 8. Each of these implementations is described in an example embodiment whereby the input to the transceiver circuitry 124 from the line driver 804 of the electrical signaling interface 152 and the output of the transceiver circuitry 124 to the line receiver 806 of the electrical signaling interface 152 are both single-ended electrical signaling formats.

FIG. 9 depicts an example implementation whereby the transceiver circuitry 124 operates to convert the electrical signaling from the electrical signaling interface 152 to optical signaling for transmission via an optical waveguide 928 (one embodiment of the transmission line 828) of the cable 101 and operates to convert the optical signaling received via an optical waveguide 930 (one embodiment of the transmission line 830) of the cable 101 to electrical signaling for reception by the electrical signaling interface 152. In this example, the driver 824 of the transceiver circuitry 124 comprises an electrical-to-optical converter a laser driver 904 and a laser diode 906. The electrical-to-optical converter further may include a pre-emphasis circuit 902. The pre-emphasis circuit 902 includes an input to receive an output signal OUT_SE from the driver 804 (FIG. 8) and an output to provide to provide a pre-emphasized signal, whereby the pre-emphasis circuit 902 improves the signal quality of the output signal OUT_SE to be transmitted by distorting the signal to compensate for distortions expected to be introduced in the signal during its transmission. The laser driver 904 comprises an input coupled to the output of the pre-emphasis circuit 902 and an output coupled to the laser diode 906, whereby the laser driver 904 is configured to drive the laser diode 906 based on the pre-emphasized signal output by the pre-emphasis circuit 902. Alternatively, the output signal OUT_SE may be supplied directly to the input of the laser driver 904. The laser diode 906, in turn, is optically coupled to the terminal of the optical waveguide 928 so as to provide for transmission over the optical waveguide 928 an optical signal representative of the electrical signal received from the line driver 804. In an alternative embodiment, a continuous wave (CW) laser (local or external) and an optical modulator driver may be implemented in place of the laser driver 904 and laser diode 906.

Conversely, the receiver 826 of the transceiver circuitry 824 comprises an optical-to-electrical converter comprising a photodiode 908 and a transimpedance amplifier (TIA) 910. The photodiode 908 is optically coupled to the optical waveguide 930 and comprises an output to provide a current representative of an optical signal received via the optical waveguide 930. The TIA 910 has an input coupled to the output of the photodiode 908 and an output, whereby the TIA 910 converts the current-based signal output by the photodiode 908 to a voltage-based single-ended signal IN_SE provided to the line receiver 806 (FIG. 8).

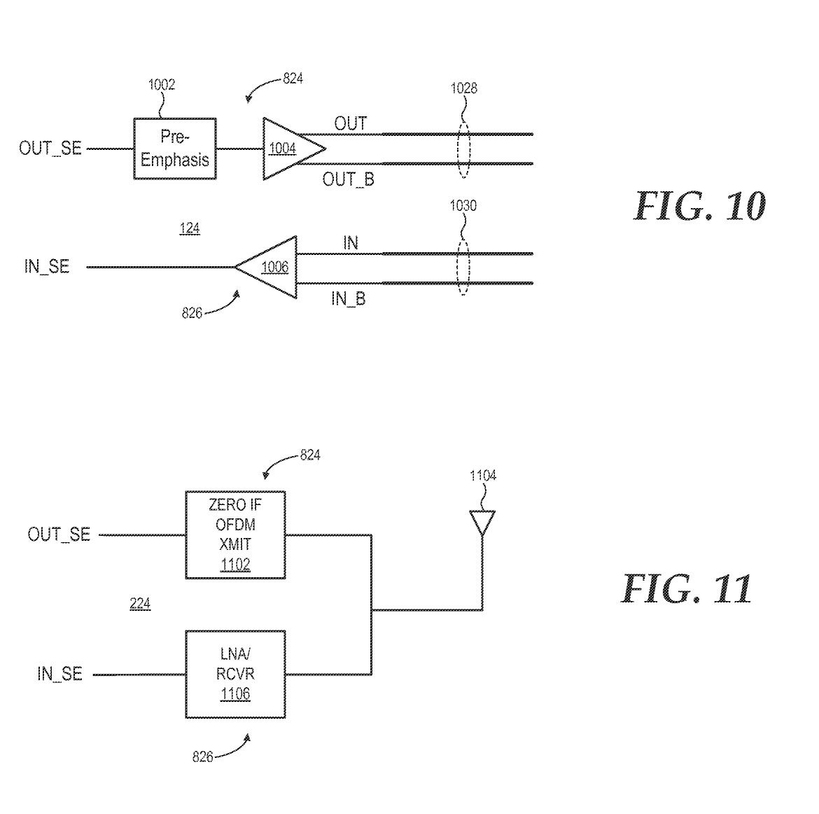

FIG. 10 depicts an example implementation whereby the transceiver circuitry 124 operates to convert the single-ended electrical signaling from the electrical signaling interface 152 to differential signaling for transmission via a wire pair 1028 (one embodiment of the transmission line 828) of the cable 101 and operates to convert differential signaling received via a wire pair 1030 (one embodiment of the transmission line 830) of the cable 101 to single-ended signaling for reception by the electrical signaling interface 152. In this example, the driver 824 of the transceiver circuitry 124 comprises a differential driver 1004, and further may include a pre-emphasis circuit 1002. The pre-emphasis circuit 1002 includes an input to receive a single-ended output signal OUT_SE from the driver 804 (FIG. 8) and an output to provide to provide a pre-emphasized signal representative of the output signal OUT_SE. The differential driver 1004 comprises a single-ended input coupled to the output of the pre-emphasis circuit 1002 and a differential output coupled to the wire pair 1028, whereby the differential driver 1004 is configured to convert the single-ended signal output by the pre-emphasis circuit 1002 to a fully differential signal comprising signal components OUT and OUT_B (OUT_B being an inverted or phase-shifted representation of OUT). Alternatively, the output signal OUT_SE may be provided directly to the input of the differential driver 1004. The signal component OUT is transmitted via one of the wires of the wire pair 1028 and the signal component OUT_B transmitted via the other wire of the wire pair 1028.

Conversely, the receiver 826 of the transceiver circuitry 824 comprises a differential-to-single-ended receiver 1006 comprising an input to receive a differential signal from the wire pair 1030, the received differential signal comprising signal components IN and IN_B (IN_B being an inverted or phase shifted representation of IN) and an output, whereby the receiver 1006 converts the received differential signal to a voltage-based single-ended signal IN_SE, which is then provided to the line receiver 806.

FIG. 11 depicts an example implementation whereby the transceiver circuitry 224 (FIG. 2) operates to convert the single-ended electrical signaling from the electrical signaling interface 152 to wireless signaling transmitted to another wireless transceiver module (e.g., external transceiver module 214 of FIG. 2) and operates to convert wireless signaling received from the other wireless transceiver module to single-ended electrical signaling for reception by the electrical signaling interface 152. In this example, the driver 824 of the transceiver circuitry 224 comprises RF transmitter 1102 coupled to one or more antennas 1104. The RF transmitter 1102 can include, for example, a zero intermediate frequency (IF) (also referred to as a “heterodyne”) orthogonal frequency division multiplexing (OFDM) transceiver, a superheterodyne transmitter, and the like. The RF transmitter 1102 includes an input to receive a single-ended electrical output signal OUT_SE from the driver 804 (FIG. 8) and an output to coupled to the at least one antenna 1104, whereby the RF transmitter 1102 is configured to convert the single-ended output signal OUT_SE to an RF signal for transmission by the antenna 1104. In this embodiment, the receiver 826 of the transceiver circuitry 824 comprises a wireless receiver 1106, such as a low noise amplifier (LNA), comprising an input to receive an RF signal from the antenna 1104 and an output to provide a single-ended electrical signal IN_SE representative of the received RF signal, which is then provided to the line receiver 806.

In at least one embodiment, the apparatus and techniques described above are implemented in a system comprising one or more integrated circuit (IC) devices (also referred to as integrated circuit packages or microchips), such as the IC packages 102 and 104 and the external transceiver modules 112, 114, 212, and 214. Electronic design automation (EDA) and computer aided design (CAD) software tools may be used in the design and fabrication of these IC devices. These design tools typically are represented as one or more software programs. The one or more software programs comprise code executable by a computer system to manipulate the computer system to operate on code representative of circuitry of one or more IC devices so as to perform at least a portion of a process to design or adapt a manufacturing system to fabricate the circuitry. This code can include instructions, data, or a combination of instructions and data. The software instructions representing a design tool or fabrication tool typically are stored in a computer readable storage medium accessible to the computing system. Likewise, the code representative of one or more phases of the design or fabrication of an IC device may be stored in and accessed from the same computer readable storage medium or a different computer readable storage medium.

A computer readable storage medium may include any storage medium, or combination of storage media, accessible by a computer system during use to provide instructions and/or data to the computer system. Such storage media can include, but is not limited to, optical media (e.g., compact disc (CD), digital versatile disc (DVD), Blu-Ray disc), magnetic media (e.g., floppy disc, magnetic tape, or magnetic hard drive), volatile memory (e.g., random access memory (RAM) or cache), non-volatile memory (e.g., read-only memory (ROM) or Flash memory), or microelectromechanical systems (MEMS)-based storage media. The computer readable storage medium may be embedded in the computing system (e.g., system RAM or ROM), fixedly attached to the computing system (e.g., a magnetic hard drive), removably attached to the computing system (e.g., an optical disc or Universal Serial Bus (USB)-based Flash memory), or coupled to the computer system via a wired or wireless network (e.g., network accessible storage (NAS)).

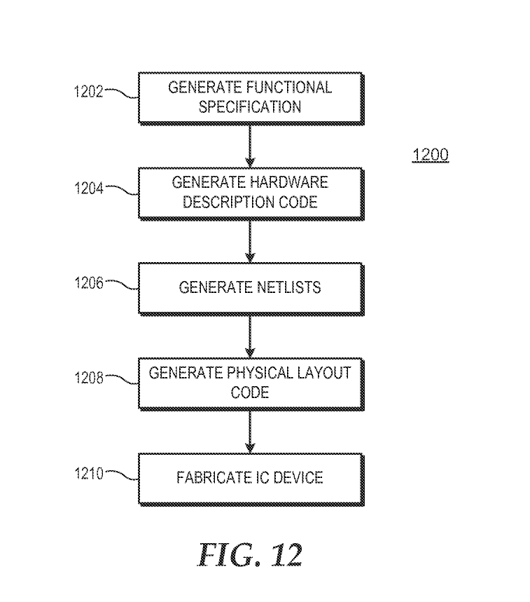

FIG. 12 is a flow diagram illustrating an example method 1200 for the design and fabrication of an IC device implementing one or more aspects of the present invention in accordance with at least one embodiment of the present disclosure. As noted above, the code generated for each of the following processes is stored or otherwise embodied in computer readable storage media for access and use by the corresponding design tool or fabrication tool.

At block 1202 a functional specification for the IC device is generated. The functional specification (often referred to as a micro architecture specification (MAS)) may be represented by any of a variety of programming languages or modeling languages, including C, C++, SystemC, Simulink, or MATLAB.

At block 1204, the functional specification is used to generate hardware description code representative of the hardware of the IC device. In at least one embodiment, the hardware description code is represented using at least one Hardware Description Language (HDL), which comprises any of a variety of computer languages, specification languages, or modeling languages for the formal description and design of the circuits of the IC device. The generated HDL code typically represents the operation of the circuits of the IC device, the design and organization of the circuits, and tests to verify correct operation of the IC device through simulation. Examples of HDL include Analog HDL (AHDL), Verilog HDL, SystemVerilog HDL, and VHDL. For IC devices implementing synchronized digital circuits, the hardware descriptor code may include register transfer level (RTL) code to provide an abstract representation of the operations of the synchronous digital circuits. For other types of circuitry, the hardware descriptor code may include behavior-level code to provide an abstract representation of the circuitry's operation. The HDL model represented by the hardware description code typically is subjected to one or more rounds of simulation and debugging to pass design verification.

After verifying the design represented by the hardware description code, at block 1206 a synthesis tool is used to synthesize the hardware description code to generate code representing or defining an initial physical implementation of the circuitry of the IC device. In one embodiment, the synthesis tool generates one or more netlists comprising circuit device instances (e.g., gates, transistors, resistors, capacitors, inductors, diodes, etc.) and the nets, or connections, between the circuit device instances. Alternatively, all or a portion of a netlist can be generated manually without the use of a synthesis tool. As with the hardware description code, the netlists may be subjected to one or more test and verification processes before a final set of one or more netlists is generated.

Alternatively, a schematic editor tool can be used to draft a schematic of circuitry of the IC device and a schematic capture tool then may be used to capture the resulting circuit diagram and to generate one or more netlists (stored on a computer readable media) representing the components and connectivity of the circuit diagram. The captured circuit diagram may then be subjected to one or more rounds of simulation for testing and verification.

At block 1208, one or more EDA tools use the netlists produced at block 1206 to generate code representing the physical layout of the circuitry of the IC device. This process can include, for example, a placement tool using the netlists to determine or fix the location of each element of the circuitry of the IC device. Further, a routing tool builds on the placement process to add and route the wires needed to connect the circuit elements in accordance with the netlist(s). The resulting code represents a three-dimensional model of the IC device. The code may be represented in a database file format, such as, for example, the Graphic Database System II (GDSII) format. Data in this format typically represents geometric shapes, text labels, and other information about the circuit layout in hierarchical form.

At block 1210, the physical layout code (e.g., GDSII code) is provided to a manufacturing facility, which uses the physical layout code to configure or otherwise adapt fabrication tools of the manufacturing facility (e.g., through mask works) to fabricate the IC device. That is, the physical layout code may be programmed into one or more computer systems, which may then control, in whole or part, the operation of the tools of the manufacturing facility or the manufacturing operations performed therein.

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed.

Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

What is claimed is:

1. An integrated circuit (IC) package comprising:
a plurality of electrical contacts disposed at a first surface of the IC package;
an integrated circuit implementing an electrical signaling interface; and
a connector assembly accessible at a second surface of the IC package, the connector assembly to mechanically attach to another connector assembly and comprising a plurality of contact terminals electrically coupled to the electrical signaling interface.

2. The IC package of claim 1, wherein the connector assembly comprises a socket assembly with a socket opening to provide friction coupling with a corresponding terminal plug assembly of the other connector assembly.

3. The IC package of claim 2, further comprising an encapsulating structure having an aperture positioned at the second surface of the IC package and aligned with the socket opening.

4. The IC package of claim 1, wherein the connector assembly comprises a terminal plug assembly to provide friction coupling with a corresponding socket opening of a socket assembly of the other connector assembly.

5. The IC package of claim 4, further comprising an encapsulating structure having an aperture positioned at the second surface of the IC package and aligned with the terminal plug assembly.

6. The IC package of claim 1, wherein the second surface is substantially perpendicular to the first surface.

7. The IC package of claim 1, wherein the second surface is opposite the first surface.

8. The IC package of claim 1, wherein the electrical signaling interface comprises at least one of:
a single-ended line driver having an output coupled to a contact terminal of the plurality of contact terminals; and
a single-ended line receiver having an input coupled to a contact terminal of the plurality of contact terminals.

9. A system comprising the IC package of claim 8, the system further comprising:
a fiber optic cable comprising:
an optical waveguide; and
a cable head fixedly attached to the optical waveguide, the cable head comprising:
a connector assembly mechanically attached to the connector assembly of the IC package; and
an electrical-to-optical signal converter comprising an input coupled to the single-ended line driver via the connector assemblies and comprising an output coupled the optical waveguide.

10. A system comprising the IC package of claim 8, the system further comprising:
a wireless transceiver module comprising:
a connector assembly mechanically attached to the connector assembly of the IC package;
an antenna; and
a radio frequency (RF) transceiver comprising an input coupled to the single-ended line driver via the connector assemblies and comprising an output coupled the antenna.

11. A system comprising the IC package of claim 8, the system further comprising:
a cable comprising:
a wire pair;
a cable head fixedly attached to the wire pair, the cable head comprising:
a connector assembly mechanically attached to the connector assembly of the IC package; and
a differential driver comprising an input coupled to the single-ended line driver via the connector assemblies and comprising an output coupled to the wire pair.

12. A system comprising the IC package of claim 1, the system further comprising:
a transceiver module external to the IC package, the transceiver module comprising:
a connector assembly mechanically attached to the connector assembly of the IC package;
a transmission medium; and
a signal conversion circuit comprising a first terminal coupled to the electrical signal interface via the connector assemblies and a second terminal coupled to the transmission medium.

13. The system of claim 12, wherein:
the transceiver module comprises a fiber optic cable;
the transmission medium comprises an optical waveguide; and
the signal conversion circuit is disposed at a cable head of the fiber optic cable and comprises at least one of an electrical-to-optical signal converter and an optical-to-electrical signal converter.

14. The system of claim 12, wherein:
the transceiver module comprises an electrical cable assembly;
the transmission medium comprises a pair of electrically conductive wires; and
the signal conversion circuit comprises at least one of a differential-signal transmitter and a differential-signal receiver.

15. The system of claim 12, wherein:
the transceiver module comprises a wireless transceiver module;
the transmission medium comprises an antenna; and
the signal conversion circuit comprises at least one of a radio frequency (RF) transmitter and an RF receiver.

16. A computer readable medium storing code which is operable to manipulate at least one computer system to perform a portion of a process to fabricate at least part of the IC package of claim 1.

17. An integrated circuit (IC) package comprising:
a plurality of electrical contacts disposed at a first surface of the IC package;
a die implementing a driver and a receiver;
a first connector assembly to removably attach to another connector assembly, the first connector assembly comprising:
a socket opening to provide friction coupling with a corresponding terminal plug of another connector assembly; and
a plurality of contact terminals, the plurality of contact terminals including a contact terminal coupled to an input of the receiver and a contact terminal coupled to an output of the driver; and
an encapsulant structure substantially enclosing the die and the first connector assembly, the encapsulant structure comprising a first aperture at a second surface of the IC package, the first aperture aligned with the socket opening.

18. The IC package of claim 17, wherein the first surface comprises a bottom surface of the IC package and the second surface comprises a side surface of the IC package.

19. The IC package of claim 17, wherein the first surface comprises a bottom surface of the IC package and the second surface comprises a top surface of the IC package.

20. The IC package of claim 17, further comprising:
a second connector assembly to removably attach with another connector assembly, the second connector assembly comprising:
a socket opening to provide friction coupling with a corresponding terminal plug of another connector assembly; and
a plurality of contact terminals, the plurality of contact terminals including a first contact terminal coupled to the first die and a second contact terminal coupled to the first die; and
wherein the encapsulant structure substantially encloses the second connector assembly and comprises a second aperture at a surface of the IC package, the second aperture aligned with the socket opening of the second connector assembly.

21. The IC package of claim 20, wherein the second aperture is at the second surface.

22. The IC package of claim 17, wherein the first die comprises a package substrate of the IC package.

23. The IC package of claim 17, further comprising:
a package substrate; and
wherein the plurality of electrical contacts are disposed at a first surface of the package substrate;
wherein the first die comprises a flip chip disposed at a second surface of the package substrate, the second surface opposite the first surface; and
wherein the first connector assembly is electrically coupled to the driver and the receiver via one or more metal layers of the package substrate.

24. The IC package of claim 17, wherein:
the driver comprises a single-ended driver; and
the receiver comprises a single-ended receiver.

25. A computer readable medium storing code which is operable to manipulate at least one computer system to perform a portion of a process to fabricate at least part of the IC package of claim 17.

26. A method comprising:
receiving power at an integrated circuit (IC) package via at least one of a plurality of electrical contacts disposed at a first surface of the IC package;
communicating a first representation of a first signal from an integrated circuit of a die of the IC package to a first connector assembly of the IC package, the first connector assembly mechanically attached at a second surface of the IC package to a corresponding second connector assembly of a transceiver module external to the IC package;
transmitting the first representation of the first signal from the first connector assembly to the second connector assembly;
converting the first representation of the first signal to a second representation of the first signal at the transceiver module; and
transmitting the second representation of the signal via the transceiver module.

27. The method of claim 26, wherein:
the transceiver module comprises a cable head of a fiber optic cable; and
the first representation of the first signal comprises an electrical representation of the first signal and the second representation of the first signal comprises an optical representation of the first signal.

28. The method of claim 26, wherein:
the transceiver module comprises a wireless transceiver module; and
the first representation of the first signal comprises an electrical representation of the first signal and the second representation of the first signal comprises a wireless representation of the first signal.

29. The method of claim 26, wherein:
the transceiver module comprises a cable head of a cable comprising a wire pair; and
the first representation of the first signal comprises a single-ended electrical representation of the first signal and the second representation of the first signal comprises a differential representation of the first signal.

30. The method of claim 26, further comprising:
receiving a first representation of a second signal at the transceiver module;
converting the first representation of the second signal to a second representation of the second signal at the transceiver module; and
transmitting the second representation of the second signal from the transceiver module to the integrated circuit via the second connector assembly and the first connector assembly.
